(19) United States
(12) Patent Application Publication
(10) Pub. No.: US 2006/0281273 A1
(43) Pub. Date: Dec. 14, 2006

(54) Semiconductor device and manufacturing method of the semiconductor device

(75) Inventors: Yukimune Watanabe, Tsukuba-shi (JP); Shinji Migita, Tsukuba-shi (JP); Nobuyuki Mise, Tsukuba-shi (JP)

Correspondence Address: OLIFF & BERRIDGE, PLC, P.O. BOX 19928, ALEXANDRIA, VA, 22320, US

(73) Assignees: SEIKO EPSON CORPORATION, Tokyo (JP); RENESAS TECHNOLOGY CORPORATION, Tokyo (JP)

(21) Appl. No.: 11/446,184

(22) Filed: Jun. 5, 2006

(30) Foreign Application Priority Data
Jun. 9, 2005 (JP) 2005-169630

(51) Int. Cl. H01L 29/76; H01L 21/336

(52) U.S. Cl. 438/305; 257/288

(57) ABSTRACT

A semiconductor device includes a gate electrode disposed on a semiconductor layer via a gate insulating film; a source layer formed in the semiconductor layer to be separated by a first offset length from one end of said gate electrode; a drain layer formed in the semiconductor layer to be separated by a second offset length from the other end of said gate electrode; a first side wall formed at a side wall of said gate electrode at a side of said source layer; and a second side wall formed at the side wall of said gate electrode at a side of said drain layer, wherein the first offset length is shorter than the second offset length, and a length of said first side wall is shorter than a length of said second side wall.

The entire disclosure of Japanese Patent Application No. 2005-169630, filed Jun. 9, 2005, is expressly incorporated by reference herein.

### BACKGROUND

1. Field of the Invention

The present invention relates to a semiconductor device and a manufacturing method of the semiconductor device, and particularly is preferable for application in a field-effect transistor having a source/drain offset structure.

2. Description of the Related Art

In the field-effect transistors of recent years, gate lengths are shortened to a submicron order to promote densification and speedup of semiconductor integrated circuits.

For example, JP-A-2004-172631 discloses a method for forming source/drain layers to be shallow to suppress a short channel effect of a field-effect transistor with its gate length reduced.

However, when the gate length of a field-effect transistor is reduced to about 50 nm or less, the control power of channel potential by a gate electrode reduces, and a leakage current flowing between a source and a drain increases. Therefore, in the field-effect transistor in which the gate length is reduced to about 50 nm or less, it becomes difficult to suppress a short channel effect sufficiently, thus causing the problems that a leakage current in an off state of the field-effect transistor increases, and that decrease in the operating current in an on state is caused.

### SUMMARY

It is an object of the present invention to provide a semiconductor device in which a gate length is capable of being reduced while reduction in control power of channel potential is suppressed, and a manufacturing method of the semiconductor device.

In order to attain the above-described object, a semiconductor device according to one aspect of the present invention is characterized by including a gate electrode disposed on a semiconductor layer via a gate insulating film, a source layer formed in the semiconductor layer to be separated by a first offset length from one end of the aforesaid gate electrode, a drain layer formed in the semiconductor layer to be separated by a second offset length from the other end of the aforesaid gate electrode, a first side wall formed at a side wall of the aforesaid gate electrode at a side of the aforesaid source layer, and a second side wall formed at the side wall of the aforesaid gate electrode at a side of the aforesaid drain layer, and characterized in that the first offset length is shorter than the second offset length, and a length of the aforesaid first side wall is shorter than a length of the aforesaid second side wall.

Thereby, it becomes possible to shorten the gate length without reducing the space between the source and drain, and the offset lengths at the source side and the drain side can be made to differ in a self-aligned manner. Therefore, when the gate length is smaller than the space between the source and drain, the control position of the potential between the source and drain can be also optimized, and it also becomes possible to suppress reduction in the control power of the channel potential while suppressing an increase in the leakage current flowing between the source and drain. As a result, the on current can be increased while an increase of the off current of the field-effect transistor is suppressed, and it becomes possible to promote densification and speedup of the semiconductor integrated circuit while reducing power consumption of the semiconductor integrated circuit.

Further, a semiconductor device according to one aspect of the present invention is characterized in that when built-in potential between the aforesaid source layer and a channel is set at V_{bi}, drain voltage at a time of operation is set at V_{D}, the first offset length is set at X_{S} and the second offset length is set at X_{D}, X_{S}/X_{D}=V_{bi}/(V_{bi}+V_{D}) is satisfied.

Thereby, when the gate length is smaller than the space between the source and drain, it also becomes possible to perform potential control by the gate electrode efficiently, and the on current can be increased while increase in the off current of the field-effect transistor is suppressed.

A semiconductor device according to one aspect of the present invention is characterized by including a gate electrode disposed on a semiconductor layer via a gate insulating film, a source layer formed in the semiconductor layer to be separated by a predetermined space from one end of the aforesaid gate electrode, a drain layer formed in the semiconductor layer to be separated by a predetermined space from the other end of the aforesaid gate electrode, a first side wall formed at a side wall of the aforesaid gate electrode at a side of the aforesaid source layer, and a second side wall formed at a side wall of the aforesaid gate electrode at a side of the aforesaid drain layer, and characterized in that dielectric constants of the aforesaid first side wall and the aforesaid second side wall are larger than a dielectric constant of the gate insulating film.

Thereby, potential control of the channel region can be efficiently performed via the side wall of the gate electrode. Therefore, when the source/drain layers are disposed to be separated from the gate electrode, it also becomes possible to suppress reduction in the control power of the channel potential by the gate electrode, and the on current can be increased while increase in the off current of the field-effect transistor is suppressed.

Further, a semiconductor device according to one aspect of the present invention is characterized by including a gate electrode disposed on a semiconductor layer via a gate insulating film, a source layer formed in the semiconductor layer to be separated by a predetermined space from one end of the aforesaid gate electrode, a drain layer formed in the semiconductor layer to be separated by a predetermined space from the other end of the aforesaid gate electrode, a first side wall formed at a side wall of the aforesaid gate electrode at a side of the aforesaid source layer, and a second side wall formed at a side wall of the aforesaid gate electrode at a side of the aforesaid drain layer, and characterized in that a dielectric constant of the aforesaid first side wall is larger than a dielectric constant of the aforesaid second side wall.

Thereby, when the source/drain layers are disposed to be separated from the gate electrode, it also becomes possible to perform potential control of the channel region at the source side efficiently and to reduce capacity at the drain side, and it becomes possible to promote densification and speedup of the semiconductor integrated circuit while reducing power consumption of the semiconductor integrated circuit.

A manufacturing method of a semiconductor device according to one aspect of the present invention is characterized by including the steps of forming a gate electrode disposed via a gate insulating film on a semiconductor layer, forming a dielectric film on an entire surface of a semiconductor layer above which the gate electrode is disposed, by irradiating ion beams obliquely to the gate electrode, forming a damage layer locally disposed at one side of the gate electrode in the dielectric film, by performing anisotropic etching of the dielectric film on which the damage layer is formed, forming a first side wall at a side wall at one side of the gate electrode, and forming a second side wall which is longer than the first side wall at a side wall at the other side of the gate electrode, and by performing ion-implantation into the semiconductor layer with the gate electrode, the first side wall and the second side wall as a mask, forming a source layer disposed to be separated by a first offset length from one end of the gate electrode in the semiconductor layer, and forming a drain layer disposed to be separated by a second offset length from the other end of the gate electrode in the semiconductor layer.

Thereby, the side walls differing in length from each other can be formed at the side wall of the gate electrode without performing mask alignment. Therefore, when the gate electrode is miniaturized, the offset lengths at the source side and the drain side can be also made to differ in a self-aligned manner, and the control position of the potential between the source and drain can be optimized.

Further, a manufacturing method of a semiconductor device according to one aspect is characterized by including the steps of forming a gate electrode disposed via a gate insulating film on a semiconductor layer, forming a first dielectric film on an entire surface on a semiconductor layer above which the gate electrode is disposed, by irradiating ion beams obliquely to the gate electrode, forming a damage layer locally disposed at one side of the gate electrode in the first dielectric film, by performing anisotropic etching of the first dielectric film on which the damage layer is formed, removing the first dielectric film at a side wall at one side of the gate electrode, and forming a first side wall at a side wall at the other side of the gate electrode, forming a second dielectric film differing in dielectric constant from the first dielectric film on an entire surface on the semiconductor layer at which the first side wall is formed, by performing anisotropic etching of the second dielectric film, forming a second side wall at the side wall of the gate electrode from which the first dielectric film is removed, and by performing ion-implantation into the semiconductor layer with the gate electrode, the first side wall and the second side wall as a mask, forming a source layer disposed to be separated by a predetermined space from one end of the gate electrode in the semiconductor layer, and forming a drain layer disposed to be separated by a predetermined space from the other end of the gate electrode in the semiconductor layer.

Thereby, it becomes possible to form the side walls differing in dielectric constant from each other at a side wall of the gate electrode, and the source/drain layer can be disposed with respect to these side walls in a self-aligned manner. Therefore, when the gate electrode is miniaturized, it also becomes possible to perform potential control of the channel region at the source side efficiently and to reduce the capacity at the drain side, and it becomes possible to promote densification and speedup of the semiconductor integrated circuit while reducing power consumption of the semiconductor integrated circuit.

### BRIEF DESCRIPTION OF THE DRAWINGS

FIGS. 1A and 1B are sectional views showing a schematic construction of a semiconductor device according to a first embodiment of the present invention, and a potential diagram;

FIG. 2 is a view showing a construction used for simulation of the characteristics of the semiconductor device in FIG. 1A;

FIGS. 3A and 3B are diagrams showing potential distributions when the dielectric constant of a spacer is changed;

FIG. 4 is a diagram showing V_{G}-I_{D} characteristics when the dielectric constant of the spacer is changed;

FIGS. 5A to 5C are diagrams showing potential distributions when the offset lengths are changed;

FIG. 6 is a diagram showing a change in an on current when the offset lengths are changed;

FIGS. 7A to 7D are sectional views showing a manufacturing method of a semiconductor device according to a second embodiment of the present invention; and

FIGS. 8A to 8F are sectional views showing a manufacturing method of a semiconductor device according to a third embodiment of the present invention.

### DETAILED DESCRIPTION OF THE PREFERRED EMBODIMENTS

Hereinafter, a semiconductor device and its manufacturing method according to embodiments of the present invention will be described with reference to the drawings.

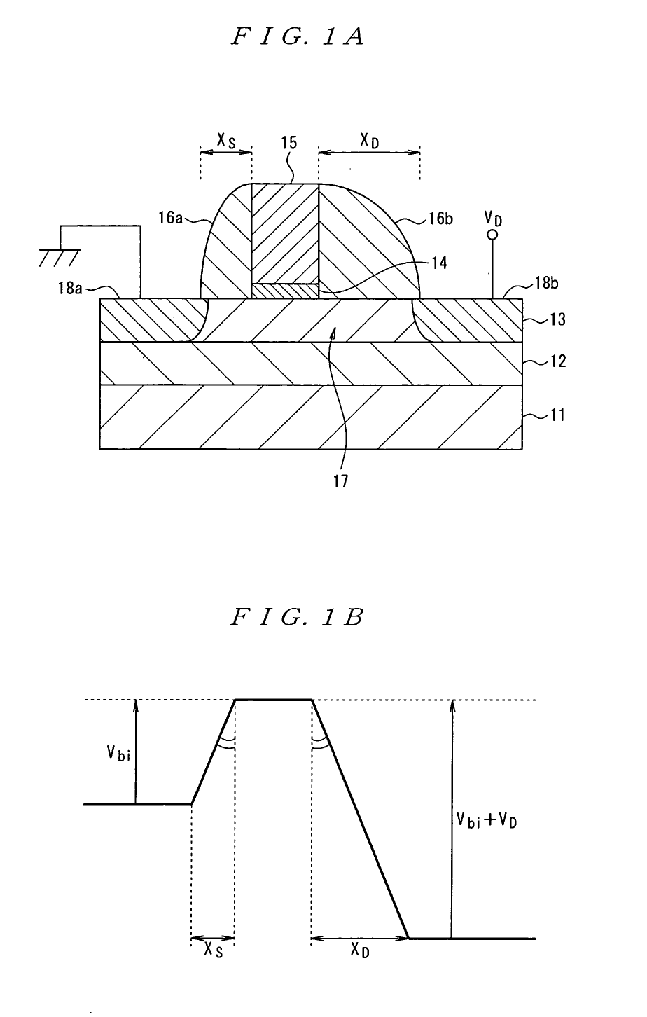

FIG. 1A is a sectional view showing a schematic construction of a semiconductor device according to a first embodiment of the present invention, and FIG. 1B is a diagram showing a potential distribution in a channel direction of the semiconductor device in FIG. 1A by approximating it by a straight line.

In FIG. 1A, an insulating layer 12 is formed on a supporting substrate 11, and a monocrystal semiconductor layer 13 is formed on the insulating layer 12. As the supporting substrate 11, a semiconductor substrate of Si, Ge, SiGe, GaAs, InP, GaP, GaN, SiC or the like may be used, or an insulating substrate of glass, sapphire, ceramics or the like may be used. As the material of the monocrystal semiconductor layer 13, for example, Si, Ge, SiGe, SiC, SiSn, PbS, GaAs, InP, GaP, GaN, ZnSe or the like can be used, and as the insulating layer 12, an insulating layer or a buried insulating film of, for example, SiO₂, SiON, Si₃N₄ or the like can be used. As the semiconductor substrate with the monocrystal semiconductor layer 13 formed on the insulating layer 12, for example, an SOI substrate can be used, and as the SOI substrate, an SIMOX (Separation by Implanted Oxygen) substrate, a bonded substrate, a laser anneal substrate or the like can be used. Instead of the monocrystal semiconductor layer 13, a polycrystalline semiconductor layer or an amorphous semiconductor layer may be used.

Agate electrode 15 is disposed on the monocrystal semiconductor layer 13 via a gate insulating film 14. As a material of the gate insulating film 14, a dielectric such as, for example, HfO₂ may be used other than SiO₂. As the material of the gate electrode 15, for example, a metal material of TaN, TiN, W, Pt, Cu or the like may be used other than polycrystalline silicon. The gate length of the gate electrode 15 is preferably set at 50 nm or less.

In the monocrystal semiconductor layer 13, a source layer 18a is formed to be separated by an offset length Xₛ from one end of the gate electrode 15, a drain layer 18b is formed to be separated by an offset length X_{D} from the other end of the gate electrode 15, and a body region 17 is disposed below the gate electrode 15. At the side of the source layer 18a, a side wall 16a formed at one side wall of the gate electrode 15 is disposed, and at the side of the drain layer 18b, a side wall 16b formed at the other side wall of the gate electrode 15 is disposed. As a material of the side walls 16a and 16b, a dielectric such as HfO₂, HfON, HfAlO, HfAlON, HfSiO, HfSiON, ZrO₂, ZrON, ZrAlO, ZrAlON, ZrSiO, ZrSiON, Ta₂O₅, Y₂O₃, (Sr, Ba) TiO₃, LaAlO₃, SrBi₂Ta₂O₉, Bi₄Ti₃O₁₂, or Pb(Zi, Ti)O₃ may be used other than SiO₂.

In this case, the offset length Xₛ at the side of the source layer 18a is preferably made shorter than the offset length X_{D} at the side of the drain layer 18b, the length of the side walls 16a and 16b can be set to correspond to the offset lengths Xₛ and X_{D}, respectively.

When the field-effect transistor in FIG. 1A is operated, the source layer 18a is grounded, a drain voltage VD is applied to the drain layer 18b, and on/off control of the gate electrode 15 can be performed.

Thereby, it becomes possible to reduce the gate length of the gate electrode 15 without decreasing a space between the source layer 18a and the drain layer 18b, and the offset lengths at the side of the source layer 18a and at the side of the drain layer 18b can be made to differ in a self-aligned manner. Therefore, when the gate length of the gate electrode 15 is smaller than the space between the source layer 18a and the drain layer 18b, a control position of potential between the source layer 18a and the drain layer 18b can be also optimized, and it becomes possible to suppress reduction in the control power on the channel potential while suppressing an increase in the leakage current flowing between the source layer 18a and the drain layer 18b. As a result, while an increase in an off current of the field-effect transistor is suppressed, an on current can be increased, and it becomes possible to promote densification and speedup of the semiconductor integrated circuit while reducing power consumption of the semiconductor integrated circuit.

As shown in FIG. 1B, when built-in potential between the source layer 18a and the channel is set at V_{bi}, the offset lengths X_{S} and X_{D} are preferably set to satisfy the following relationship.
X_{S}/X_{D}=V_{bi}/(V_{bi}+V_{D})

Thereby, even when V_{D} is applied to the drain layer 18b, a potential gradient of the offset region of the source layer 18a and a potential gradient of the offset region of the drain layer 18b side can be also made equal. Therefore, even when the gate length of the gate electrode 15 is smaller than the space between the source layer 18a and the drain layer 18b, control power of the channel potential by the gate electrode 15 can be equalized, and the potential control by the gate electrode can be efficiently performed.

The dielectric constants of the side walls 16a and 16b are preferably set to be larger than the dielectric constant of the gate insulating film 14. Thereby, the potential control of the channel region can be efficiently performed via the side walls of the gate electrode 15, and when the source layer 18a and the drain layer 18b are disposed to be separated from the gate electrode 15, it also becomes possible to suppress reduction in the control power of the channel potential by the gate electrode 15.

The dielectric constant of the side wall 16a at the source layer 18a side is preferably set to be larger than the dielectric constant of the side wall 16b at the drain layer 18b side. Thereby, it becomes possible to perform potential control of the channel region of the source layer 18a efficiently, and it becomes possible to reduce capacity at the side of the drain layer 18b.

In the embodiment of FIGS. 1A and 1B, the method for forming a field-effect transistor on the SOI substrate is described, but the construction of FIG. 1A may be applied to a field-effect transistor formed on a bulk substrate.

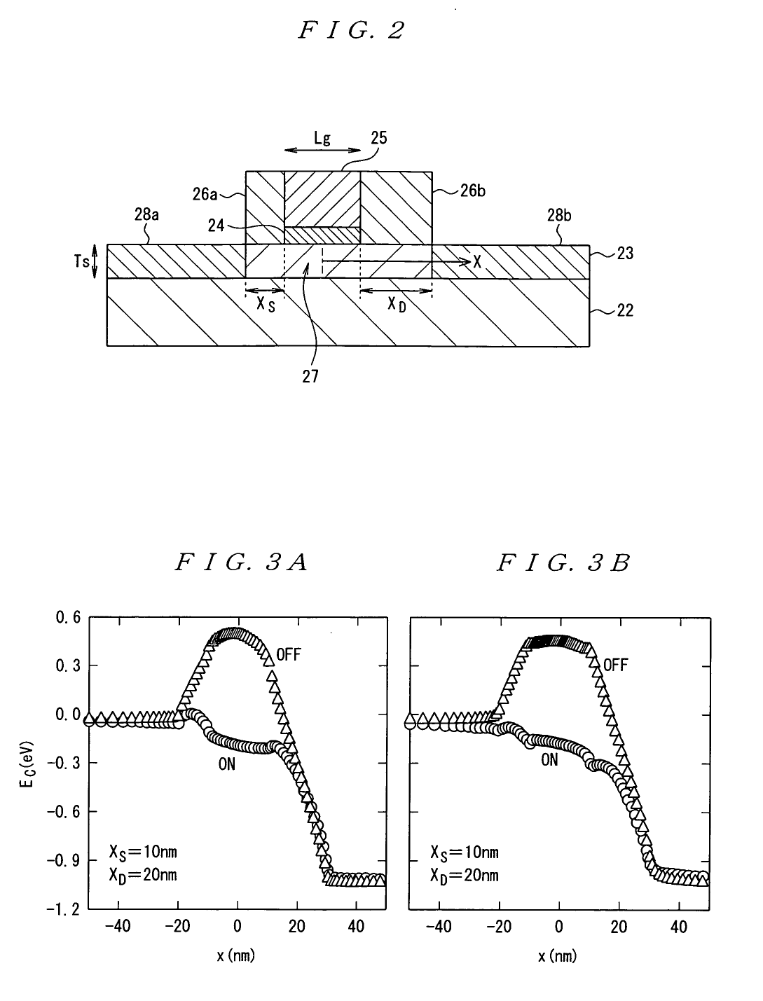

FIG. 2 is a view showing a construction used in simulation of characteristics of the semiconductor device in FIGS. 1A and 1B.

In FIG. 2, a monocrystal Si layer 23 is formed on a BOX layer 22. A gate electrode 25 is disposed on the monocrystal Si layer 23 via a gate insulating film 24. In the monocrystal Si layer 23, a source layer 28a is formed to be separated by the offset length Xₛ from one end of the gate electrode 25, while a drain layer 28b is formed to be separated by the offset length X_{D} from the other end of the gate electrode 25, and a body region 27 is disposed below the gate electrode 25. A side wall 26a formed at one side wall of the gate electrode 25 is disposed at the side of the source layer 28a, and a side wall 26b formed at the other side wall of the gate electrode 25 is disposed at the side of the drain layer 28b.

Here, a film thickness Ts of the monocrystal Si layer 23 is set at 10 nm, an impurity concentration of the monocrystal Si layer 23 is set at 10¹⁵/cm², a gate length Lg of the gate electrode 25 is set at 20 nm, a work function φ_{M} of the gate electrode 25 is set at 4.6 eV, a film thickness of the gate insulating film 24 is set at 1 nm, a relative dielectric constant of the gate insulating film 24 is set at ε_{G}, and relative dielectric constant of the side walls 26a and 26b is set as ε_{Sp}, and in the state where the source layer 28a is grounded and the drain voltage V_{D}=1V is applied to the drain layer 18b, simulation on the characteristics of the field-effect transistor in FIG. 2 is performed.

FIGS. 3A and 3B are diagrams showing simulation results of the potential distribution in a channel direction when the dielectric constants of the spacer and the gate insulating film are changed. FIG. 3A shows the potential distribution in the channel direction when the relative dielectric constant ε_{G} of the gate insulating film 24 is set at 20, and the relative dielectric constant ε_{Sp} of the side walls 26a and 26b is set at 3.9, and FIG. 3B shows the potential distribution in the channel direction when the relative dielectric constant ε_{G} of the gate insulating film 24 is set at 3.9, and the relative dielectric constant ε_{Sp} of the side walls 26a and 26b is set at 20.

In FIGS. 3A and 3B, when the relative dielectric constant ε_{G} of the gate insulating film 24 is set at 3.9, and the relative dielectric constant ε_{Sp} of the side walls 26a and 26b is set at 20, drop in the potential of the channel region when the gate electrode 25 is turned on decreases as compared with the case where the relative dielectric constant ε_{G} of the gate insulating film 24 is set at 20, and the relative dielectric constant ε_{Sp} of the side walls 26a and 26b is set at 3.9. When the relative dielectric constant ε_{G} of the gate insulating film 24 is set at 3.9, and the relative dielectric constant ε_{Sp} of the side walls 26a and 26b is set at 20, the potential of the channel region when the gate electrode 25 is turned off is flattened as compared with the case where the relative dielectric constant ε_{G} of the gate insulating film 24 is set at 20, and the relative dielectric constant ε_{Sp} of the side walls 26a and 26b is set at 3.9.

As a result, by making the dielectric constant of the side walls 26a and 26b larger than the dielectric constant of the gate insulating film 24, the control power of the channel potential by the gate electrode 25 can be increased, and the on current can be increased while increase in the off current of the field-effect transistor is suppressed.

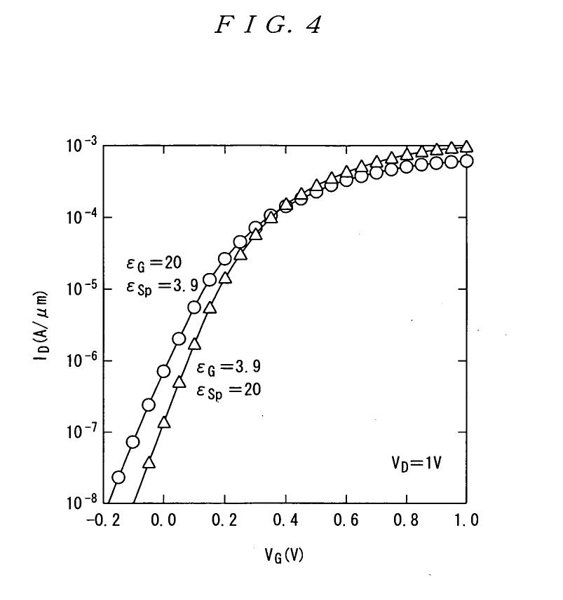

FIG. 4 is a diagram showing a simulation result of the V_{G}-I_{D} characteristics when the dielectric constants of the spacer and the gate insulating film are changed.

FIG. 4 shows that by making the dielectric constant of the side walls 26a and 26b larger than the dielectric constant of the gate insulating film 24, the off current of the field-effect transistor decreases and the on current increases.

Comparing the case where the relative dielectric constant ε_{G} of the gate insulating film 24 is set at 3.9, and the relative dielectric constant ε_{Sp} of the side walls 26a and 26b is set at 20 and the case where the relative dielectric constant ε_{G} of the gate insulating film 24 is set at 20, and the relative dielectric constant ε_{Sp} of the side walls 26a and 26b is set at 3.9, the V_{G}-I_{D} characteristics are deviated, and therefore, by changing the relative dielectric constant of the side walls 26a and 26b, threshold voltage can be regulated.

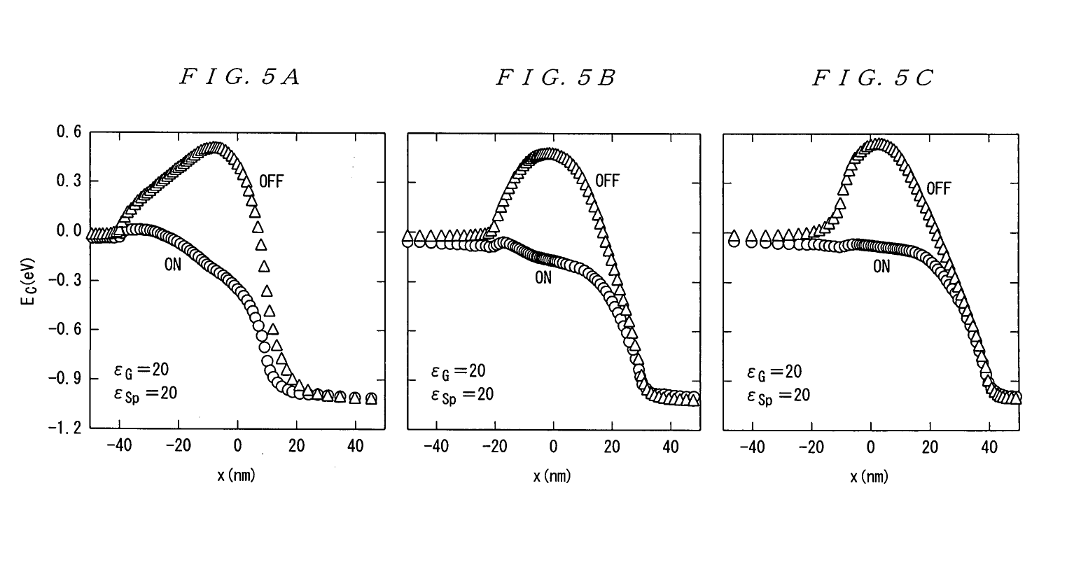

FIGS. 5A to 5C are diagrams each showing potential distribution in a channel direction when offset lengths of the source/drain are changed. FIG. 5A shows the potential distribution in the channel direction when the relative dielectric constant ε_{G} of the gate insulating film 24 is set at 20, the relative dielectric constant ε_{Sp} of the side walls 26a and 26b is set at 20, the offset length Xₛ is set at 30 nm, and the offset length X_{D} is set at 0 nm, FIG. 5B shows the potential distribution in the channel direction when the relative dielectric constant ε_{G} of the gate insulating film 24 is set at 20, the relative dielectric constant ε_{Sp} of the side walls 26a and 26b is set at 20, the offset length Xₛ is set at 10 nm, and the offset length X_{D} is set at 20 nm, and FIG. 5C shows the potential distribution in the cannel direction when the relative dielectric constant ε_{G} of the gate insulating film 24 is set at 20, the relative dielectric constant ε_{Sp} of the side walls 26a and 26b is set at 20, the offset length Xₛ is set at 0 nm, and the offset length X_{D} is set at 30 nm.

In FIGS. 5A to 5C, by changing the distribution ratio of the offset length X_{S} and X_{D}, the potential of the channel region when the gate electrode 25 is turned on/off can be changed, and the control power of the channel potential by the gate electrode 25 can be controlled.

When the offset length of the source/drain is changed, the peak of the potential of the channel region at an off time changes, and therefore, by changing the offset length of the source/drain, the threshold voltage can be regulated.

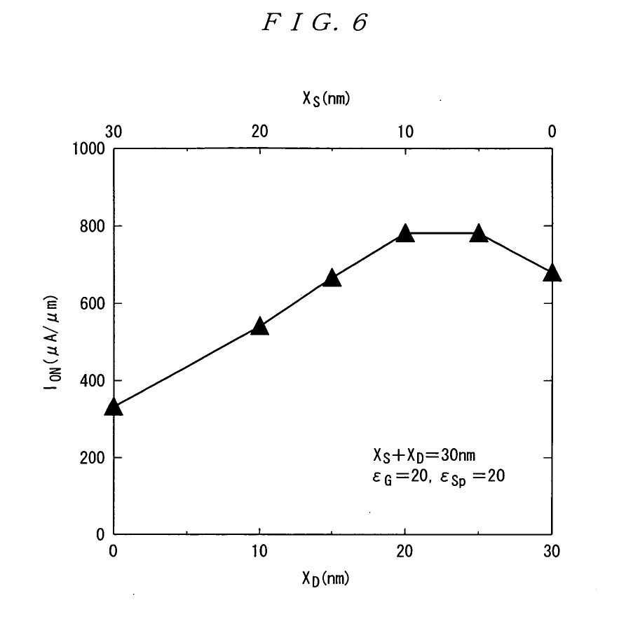

FIG. 6 is a diagram showing a change in the on current when the offset lengths of the source/drain are changed.

In FIG. 6, when the relative dielectric constant ε_{G} of the gate insulating film 24 is set at 20, the relative dielectric constant ε_{Sp} of the side walls 26a and 26b is set at 20, X_{S}+X_{D} is fixed at 30 nm, and the distribution ratio of the offset lengths Xₛ and X_{D} is changed, the on current I_{ON} can be made maximum in the vicinity of the offset length X_{D}=20 nm. As a result, in order to increase the on current I_{ON}, it is preferable to make the offset length X_{D} larger than the offset length X_{S}.

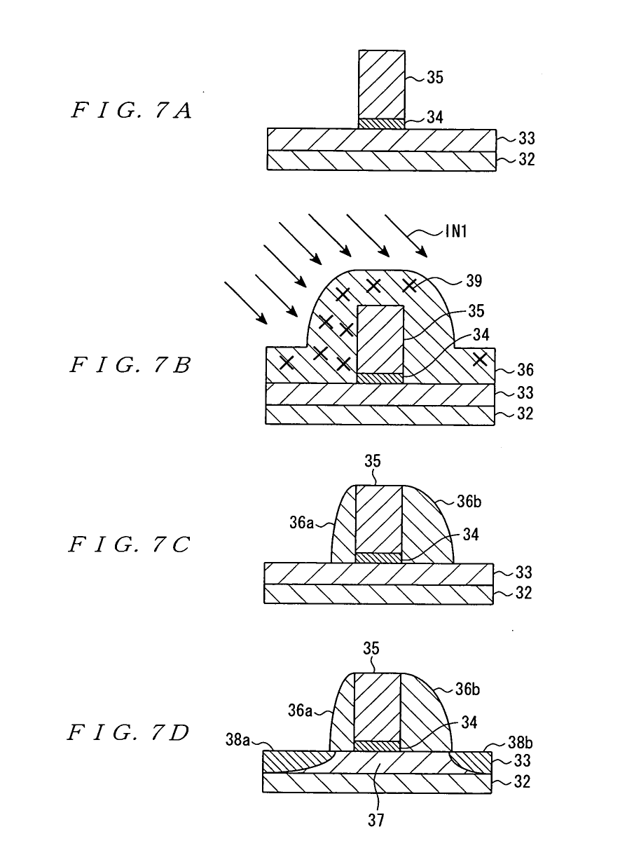

FIGS. 7A to 7D are sectional views showing one example of a manufacturing method of a semiconductor device according to a second embodiment of the present invention.

In FIG. 7A, a monocrystal semiconductor layer 33 is formed on a BOX layer 32. By performing thermal oxidation of a surface of the monocrystal semiconductor layer 33, a gate insulating film 34 is formed on a surface of the monocrystal semiconductor layer 33. Then, a polycrystalline silicon layer is formed by a method such as CVD on the monocrystal semiconductor layer 33 on which the gate insulating film 34 is formed. Then, by patterning the polycrystalline silicon layer by using the photolithography technique and etching technique, the gate electrode 35 is formed above the monocrystal semiconductor layer 33.

Next, as shown in FIG. 7B, a dielectric film 36 is deposited on an entire surface on the monocrystal semiconductor layer 33 above which a gate electrode 35 is disposed. Then, by irradiating ion beams IN1 obliquely to the gate electrode 35, a damage layer 39 locally disposed on one side of the gate electrode 35 is formed on the dielectric film 36.

Next, as shown in FIG. 7C, by performing anisotropic etching of the dielectric film 36 on which the damage layer 39 is formed, a side wall 36a is formed on a side wall at one side of the gate electrode, and a side wall 36b is formed on the side wall at the other side of the gate electrode 35. Here, by forming the damage layer 39 locally disposed at the one side of the gate electrode 35 on the dielectric film 36, the etching rate of the dielectric film 36 at the side wall 36a side can be made higher than the etching rate of the dielectric film 36 at the side wall 36b side. Therefore, the dielectric film 36 at the side wall 36a side can be made thinner than the dielectric film 36 at the side wall 36b side, and the length of the side wall 36a can be made shorter than the length of the side wall 36b.

Next, as shown in FIG. 7D, by performing ion-implantation of an impurity into the monocrystal semiconductor layer 33 with the gate electrode 35 and the side walls 36a and 36b as a mask, a source layer 38a disposed to be separated by the length of the side wall 36a from one end of the gate electrode 35 is formed in the monocrystal semiconductor layer 33, and a drain layer 38b disposed to be separated by the length of the side wall 36b from the other end of the gate electrode 35 is formed in the monocrystal semiconductor layer 33.

Thereby, when the gate electrode 35 is miniaturized, the offset lengths at the source layer 38a side and the drain layer 38b side can be caused to differ in a self-aligned manner, and the control position of the potential of a body region 37 having a source/drain offset structure can be optimized.

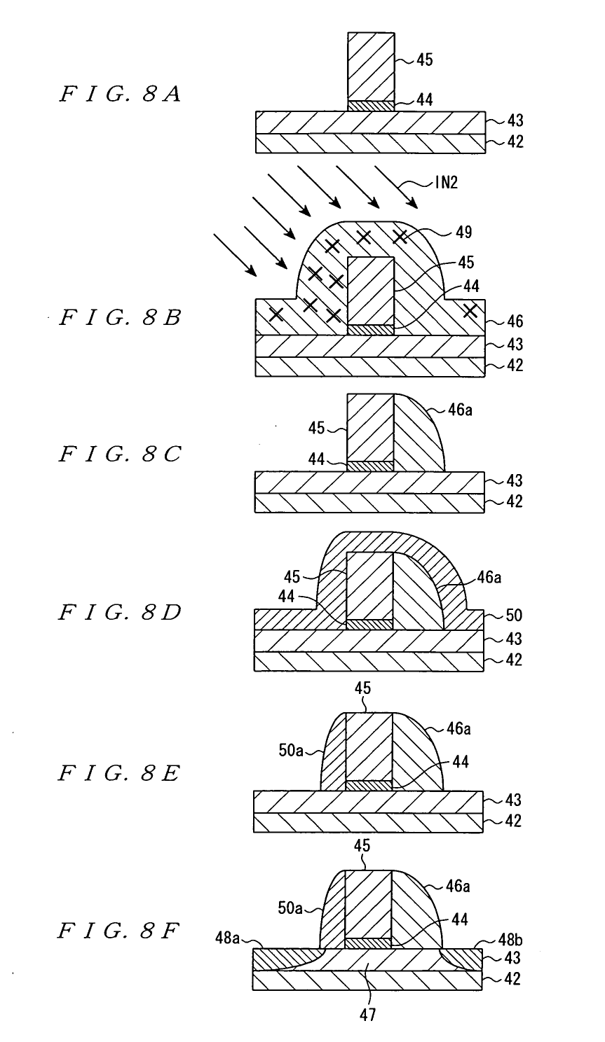

FIGS. 8A to 8F are sectional views showing one example of a manufacturing method of a semiconductor device according to a third embodiment of the present invention.

In FIG. 8A, a monocrystal semiconductor layer 43 is formed on a BOX layer 42, and a gate electrode 45 is formed on the monocrystal semiconductor layer 43 via a gate insulating film 44.

As shown in FIG. 8B, a dielectric film 46 is deposited on an entire surface on the monocrystal semiconductor layer 43 above which a gate electrode 45 is disposed. Then, by irradiating ion beams IN2 obliquely to the gate electrode 45, a damage layer 49 locally disposed on one side of the gate electrode 45 is formed on the dielectric film 46.

Next, as shown in FIG. 8C, by performing anisotropic etching of the dielectric film 46 on which the damage layer 49 is formed, the dielectric film 46 at the other side of the gate electrode 45 is removed, and a side wall 46a is formed on a side wall at the other side of the gate electrode 45.

Then, as shown in FIG. 8D, a dielectric film 50 having a different dielectric constant from the dielectric film 46 is deposited on the entire surface on the monocrystal semiconductor layer 43 on which the side wall 46a is disposed.

Next, as shown in FIG. 8E, by performing anisotropic etching of the dielectric film 50, a side wall 50a is formed on the side wall of the gate electrode 45 from which the dielectric film 46 is removed. The dielectric constant of the side wall 50a at the source layer 48a side in FIG. 8F is preferably set to be larger than the dielectric constant of the side wall 46a at a drain layer 48b side.

Next, as shown in FIG. 8F, by performing ion-implantation of an impurity into the monocrystal semiconductor layer 43 with the gate electrode 45 and the side walls 46a and 50a as a mask, the source layer 48a disposed to be separated by the length of the side wall 50a from one end of the gate electrode 45 is formed in the monocrystal semiconductor layer 43, and the drain layer 48b disposed to be separated by the length of the side wall 46a from the other end of the gate electrode 45 is formed in the monocrystal semiconductor layer 43.

Thereby, it becomes possible to form the side walls 50a and 46a differing in dielectric constant from each other at the side wall of the gate electrode 45, and the source layer 48a and the drain layer 48b are disposed with respect to the side walls 50a and 46a in a self-aligned manner. Therefore, even when the gate electrode 45 is miniaturized, it becomes possible to perform potential control of the channel region at the source layer 48a side efficiently, and to reduce the capacity of the drain layer 48b side, and it becomes possible to promote densification and speedup of the semiconductor integrated circuit while reducing power consumption of the semiconductor integrated circuit.

What is claimed is:

1. A semiconductor device, comprising:
a gate electrode disposed on a semiconductor layer via a gate insulating film;
a source layer formed in the semiconductor layer to be separated by a first offset length from one end of said gate electrode;
a drain layer formed in the semiconductor layer to be separated by a second offset length from the other end of said gate electrode;
a first side wall formed at a side wall of said gate electrode at a side of said source layer; and
a second side wall formed at the side wall of said gate electrode at a side of said drain layer,
wherein the first offset length is shorter than the second offset length, and a length of said first side wall is shorter than a length of said second side wall.

2. The semiconductor device according to claim 1,
wherein when built-in potential between said source layer and a channel is set at V_{bi}, drain voltage at a time of operation is set at V_{D}, the first offset length is set at X_{S} and the second offset length is set at X_{D},
X_{S}/X_{D}=V_{bi}/(V_{bi}+V_{D}) is satisfied.

3. A semiconductor device, comprising:
a gate electrode disposed on a semiconductor layer via a gate insulating film;
a source layer formed in the semiconductor layer to be separated by a predetermined space from one end of said gate electrode;
a drain layer formed in the semiconductor layer to be separated by a predetermined space from the other end of said gate electrode;
a first side wall formed at a side wall of said gate electrode at a side of said source layer; and
a second side wall formed at the side wall of said gate electrode at a side of said drain layer,
wherein dielectric constants of said first side wall and said second side wall are larger than a dielectric constant of the gate insulating film.

4. A semiconductor device, comprising:
a gate electrode disposed on a semiconductor layer via a gate insulating film;
a source layer formed in the semiconductor layer to be separated by a predetermined space from one end of said gate electrode;
a drain layer formed in the semiconductor layer to be separated by a predetermined space from the other end of said gate electrode;
a first side wall formed at a side wall of said gate electrode at a side of said source layer; and
a second side wall formed at a side wall of said gate electrode at a side of said drain layer,
wherein a dielectric constant of said first side wall is larger than a dielectric constant of said second side wall.

5. A manufacturing method of a semiconductor device, comprising the steps of:
forming a gate electrode disposed via a gate insulating film on a semiconductor layer;
forming a dielectric film on an entire surface of a semiconductor layer above which the gate electrode is disposed;
by irradiating ion beams obliquely to the gate electrode, forming a damage layer locally disposed at one side of the gate electrode in the dielectric film;
by performing anisotropic etching of the dielectric film on which the damage layer is formed, forming a first side wall at a side wall at one side of the gate electrode, and forming a second side wall which is longer than the first side wall at the side wall at the other side of the gate electrode; and
by performing ion-implantation into the semiconductor layer with the gate electrode, the first side wall and the second side wall as a mask, forming a source layer disposed to be separated by a first offset length from one end of the gate electrode in the semiconductor layer, and forming a drain layer disposed to be separated by a second offset length from the other end of the gate electrode in the semiconductor layer.

6. A manufacturing method of a semiconductor device, comprising the steps of:
forming a gate electrode disposed via a gate insulating film on a semiconductor layer;
forming a first dielectric film on an entire surface on a semiconductor layer above which the gate electrode is disposed;
by irradiating ion beams obliquely to the gate electrode, forming a damage layer locally disposed at one side of the gate electrode in the first dielectric film;
by performing anisotropic etching of the first dielectric film on which the damage layer is formed, removing the first dielectric film at a side wall at one side of the gate electrode, and forming a first side wall at a side wall at the other side of the gate electrode;
forming a second dielectric film differing in dielectric constant from the first dielectric film on an entire surface on the semiconductor layer at which the first side wall is formed;
by performing anisotropic etching of the second dielectric film, forming a second side wall at the side wall of the gate electrode from which the first dielectric film is removed; and
by performing ion-implantation into the semiconductor layer with the gate electrode, the first side wall and the second side wall as a mask, forming a source layer disposed to be separated by a predetermined space from one end of the gate electrode in the semiconductor layer, and forming a drain layer disposed to be separated by a predetermined space from the other end of the gate electrode in the semiconductor layer.
